(19) United States
(12) Patent Application Publication
(10) Pub. No.: US 2007/0133729 A1
(43) Pub. Date: Jun. 14, 2007

(54) Spread ratio fixing circuit and method for generating spread spectrum clock

(76) Inventors: Chiao-Wei Hsiao, Hsinchu (TW); Chun-Yi Huang, Hsinchu City (TW)

Correspondence Address: J.C. Patents, Inc., 4 Venture, Suite 250, Irvine, CA, 92618, US

(21) Appl. No.: 11/365,769

(22) Filed: Feb. 28, 2006

(30) Foreign Application Priority Data
Dec. 12, 2005 (TW) 94143855

(51) Int. Cl. H03D 3/24

(52) U.S. Cl. 375/374; 375/376

(57) ABSTRACT

An apparatus for generating a spread spectrum clock with constant spread ratio includes a resistance-capacitance oscillator which is used for generating a first clock signal. In addition, the present invention further includes a spread spectrum charge pump circuit, a loop filter, and a voltage controlled oscillator (VCO). The spread spectrum charge pump circuit generates a spread spectrum current according to the first clock signal for changing/discharging the loop filter, so as to make the loop filter generate a control voltage. The VCO generates a control current and a spread spectrum clock signal according to the control voltage. The VCO feeds the control current back to the spread spectrum charge pump circuit to generate the spread spectrum current.

### CROSS-REFERENCE TO RELATED APPLICATION

This application claims the priority benefit of Taiwan application serial no. 94143855, filed on Dec. 12, 2005. All disclosure of the Taiwan application is incorporated herein by reference.

### BACKGROUND OF THE INVENTION

1. Field of Invention

The present invention relates to an apparatus for generating a spread spectrum clock. More particularly, the present invention relates to an apparatus for generating a spread spectrum clock with constant spread ratio.

2. Description of Related Art

In recent years, the problem of electromagnetic interference (EMI) has gradually attracted attention. The clock generating apparatus' of the computer motherboard is usually the main source of EMI in the computer host. Therefore, in order to enable an ordinary phase lock loop (PLL) to restrain EMI, some changes are often made to the PLL to enable it to have a spread spectrum function to restrain EMI.

FIG. 1 is a block circuit view of a conventional PLL having an apparatus for generating the spread spectrum clock. Referring to FIG. 1, in the conventional PLL 100, a reference clock signal CLK0 is respectively sent to a phase comparator 101 and a frequency divider 103. The output of the phase comparator 101 is coupled to a charge pump circuit 105. The charge pump circuit 105 generates a voltage signal V1 to a loop filter 107 according to the output of the phase comparator. A voltage controlled oscillator (VCO) 109 generates an output clock signal CLKOUT according to the output of the loop filter 107. A frequency divider 111 receives the output clock signal CLKOUT and then generates a comparison clock signal CLKCAP to the phase comparator 101.

When the reference clock signal CLK0 and the comparison clock signal CLKCAP are sent to the phase comparator 101 at the same time, the phase comparator 101 compares the phases of the reference clock signal CLK0 and the comparison clock signal CLKCAP, and sends the comparison result to the charge pump circuit 105. Then, the charge pump circuit 105 generates a voltage signal V1 of different voltage levels to the loop filter 107 according to the comparison result of the phase comparator 101, enabling the VCO 109 to generate an output clock signal CLKOUT according to the output of the loop filter 107. The frequency divider 111 divides the frequency of the output clock signal CLKOUT, generates a comparison clock signal CLKCAP, and feeds the comparison clock signal CLKCAP back to the phase comparator 101. According to the foregoing loop, the phase of the output clock signal CLKOUT can be kept constant.

Moreover, when the reference clock signal CLK0 is sent to the frequency divider 103, the frequency of the reference clock signal CLK0 is divided by the frequency divider 103 and then sent to the spread spectrum charge pump circuit 113. Therefore, the spread spectrum charge pump circuit 113 generates a spread spectrum current Issp according to the output of the frequency divider 103 for alternately charging/discharging the loop filter 107. With the above-mentioned mechanism, the loop filter 107 can generate a triangular wave to modulate the VCO 109, allowing the VCO 109 to output the output clock signal CLKOUT modulated by the triangular wave.

FIG. 2 is a waveform chart of the triangular wave signal generated by the loop filter. Referring to FIGS. 1 and 2, Vp represents a peak voltage, Vavg represents an averaged voltage value, and the cycle t1 of the triangular wave represents a spread spectrum cycle.

If the reference clock signal CLK0 input into the frequency divider 103 is a broadband signal, reference clock signals CLK0 of different frequencies may cause different spread spectrum cycles t1, resulting in changes of the peak voltage Vp. If the peak voltage Vp changes, the ΔV will change.

### SUMMARY OF THE INVENTION

Accordingly, the invention provides a spread ratio fixing circuit applicable to a PLL, for enabling the PLL to provide a constant spread ratio under input reference clock signals of different frequencies.

In addition, the invention is to provide a method for generating a spread spectrum clock signal with constant spread ratio.

The invention provides a spread ratio fixing circuit applicable to a PLL, and the PLL is used for generating spread spectrum clock signals. Moreover, the PLL has a loop filter, and the spread ratio fixing circuit of the present invention includes a clock generating apparatus and a spread spectrum charge pump circuit. The clock generating apparatus is used for generating a first clock signal with constant frequency. The spread spectrum charge pump circuit is coupled to the loop filter for charging/discharging the loop filter according to the first clock signal, so as to load a triangular wave signal of constant frequency into a control voltage output by the loop filter.

In general, the PLL further comprises a phase comparator, a charge pump circuit, a VCO, and a frequency divider. The phase comparator outputs a comparison result to the charge pump circuit according to a feedback clock signal and a reference clock signal, so that the charge pump circuit generates a charging current in different directions to the loop filter. The VCO is coupled to the loop filter for generating a current signal and a spread spectrum clock signal according to the control voltage signal. The VCO will also feed the above current signal back to the spread spectrum charge pump circuit for controlling the amplitude of the triangular wave signal. Moreover, the frequency divider divides the frequency of the spread spectrum clock signal and generates a feedback clock signal to the phase comparator.

In the embodiment of the invention, the VCO includes a voltage/current conversion circuit and a current controlled oscillator. The voltage/current conversion circuit is used for converting a control voltage into a current signal, and the current controlled oscillator is used for generating a spread spectrum clock signal according to the current signal output by the voltage/current conversion circuit.

Furthermore, the loop filter includes a first capacitor and a second resistor. The first end of the first capacitor is grounded, and the second end is coupled to the first end of the second resistor. Besides, the loop filter further includes a first resistor and a second capacitor. Likewise, the first end of the second capacitor is also grounded, and the second end is coupled to the second end of the first resistor. The first end of the first resistor is coupled to the second end of the second resistor, and then coupled to the spread spectrum charge pump circuit together.

In general, the spread spectrum charge pump circuit includes a first switch and a second switch. The first end of the first switch is grounded via a first control current source. The on/off of the first switch is determined by the aforementioned first clock signal. The second end of the first switch is coupled to the first end of the second switch, and the second end of the second switch is coupled to a second control current source. The amount of the current output by the first current source and the amount of the current output by the second current source are the same. Moreover, the inverter receives the first clock signal so as to control the on/off of the second switch.

Preferably, the clock generating apparatus includes a resistance-capacitance oscillator.

Seen from another point of view, the invention provides a method for generating a spread spectrum clock signal, which is applicable to a PLL. The PLL has a loop filter. The implementation of the invention includes: first generating a reference clock signal; charging/discharging the loop filter based on the phase difference between the reference clock signal and the spread spectrum clock signal; then generating a first clock signal with constant frequency; similarly, charging/discharging the loop filter according to the frequency of the first clock signal for loading a triangular wave signal on a control voltage output by the loop filter; finally, generating a spread spectrum clock signal in accordance with the control voltage.

Preferably, the invention further includes converting the control voltage into a current signal, and oscillating to obtain the spread spectrum clock signal according to the current signal. Furthermore, the invention also includes feeding back the current signal so as to control the amplitude of the triangular wave signal.

In view of the above, the spread spectrum charge pump circuit of the present invention loads a triangular wave signal with constant frequency on the output of the loop filter, thus providing a constant frequency ratio of the spread spectrum, and further effectively shortening the charging time of the invention. Additionally, the present invention can keep the spread ratio constant under the reference clock signals of different frequencies.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a block circuit view of a conventional PLL with a spread spectrum clock generating apparatus.

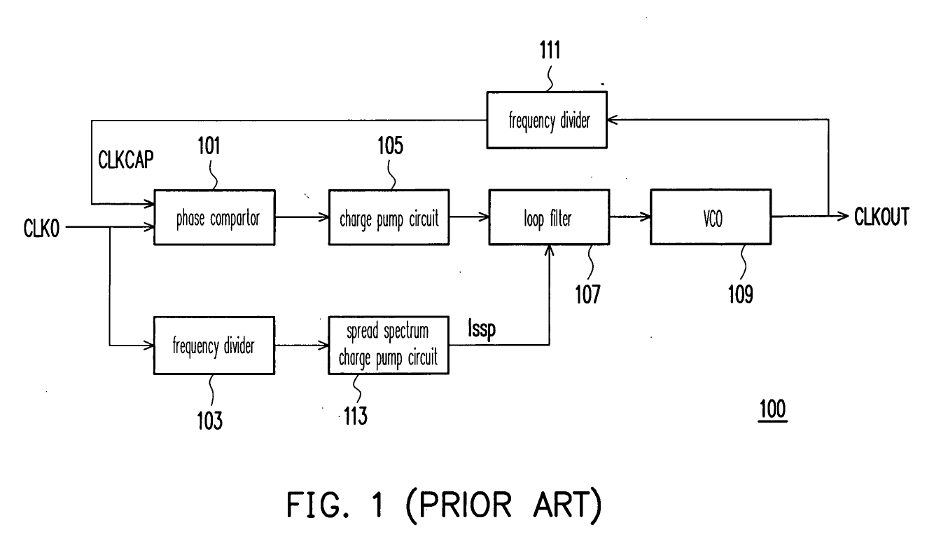

FIG. 2 is a waveform chart of the triangular wave signal generated by a loop filter.

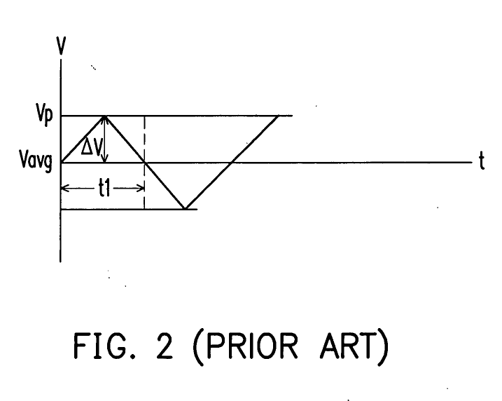

FIG. 3A is a block circuit view of a PLL with a spread ratio fixing circuit according to one preferred embodiment of the invention.

FIG. 3B is schematic view of the circuit of a spread spectrum charge pump circuit according to one preferred embodiment of the invention.

FIG. 3C is a block circuit view of a VCO according to one preferred embodiment of the invention.

FIG. 4 is a flow chart illustrating the steps for generating the spread spectrum clock signal according to one preferred embodiment of the invention.

### DESCRIPTION OF EMBODIMENTS

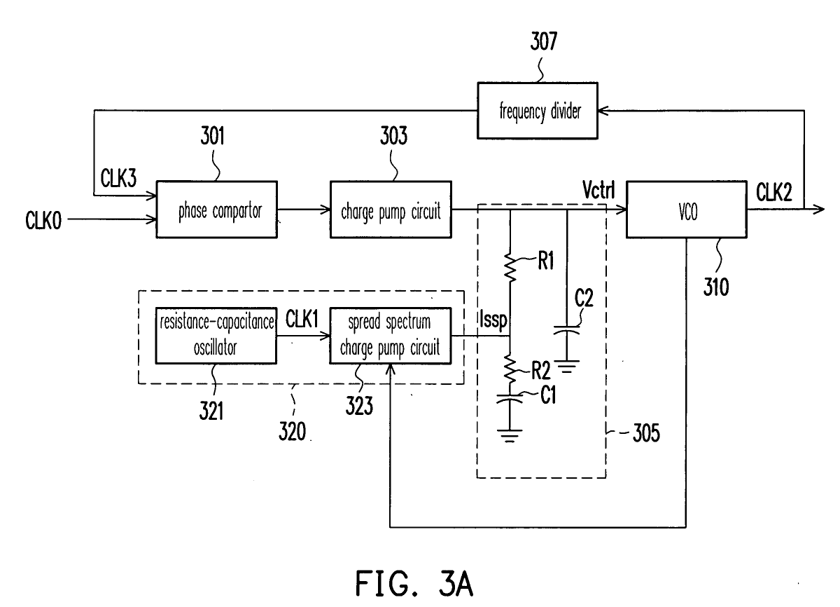

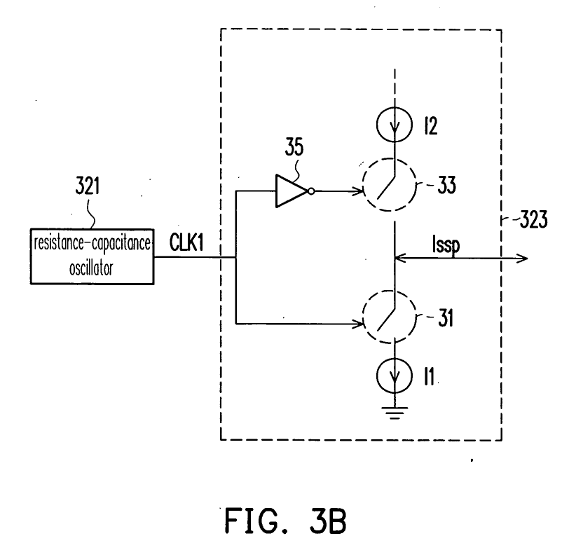

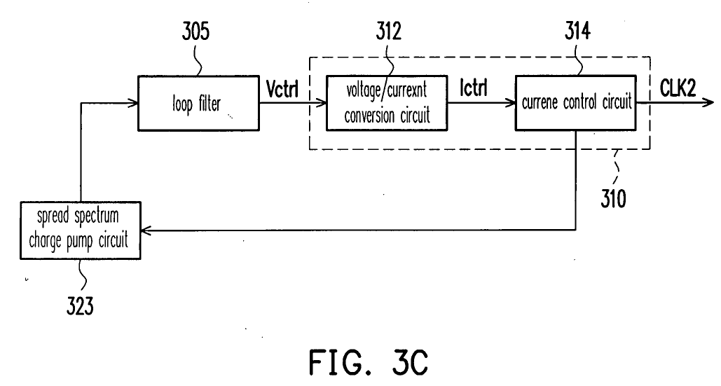

FIG. 3A is a block view of the circuit of a PLL with a constant spread ratio fixing circuit according to a preferred embodiment of the invention. Referring to FIG. 3A, the phase comparator 301 receives a reference clock signal CLK0 and a feedback clock signal CLK3, and its output is coupled to a charge pump circuit 303. The charge pump circuit 303 transmits charging current in different flow directions into the loop filter 305 according to the output of the phase comparator 301. The loop filter 305 generates a control voltage signal Vctrl to the VCO 310 according to the flow direction of the charging current sent by the charge pump circuit 303, so that the VCO 310 generates a spread spectrum clock signal CLK2. The frequency divider 307 generates a feedback clock signal CLK3 to the phase comparator 301 after dividing the frequency of the spread spectrum clock signal CLK2.

It should be noted that, in the PLL of FIG. 3A, a spread ratio fixing circuit 320 of the invention is further provided. The spread ratio fixing circuit 320 (known as a secondary circuit) is coupled to the loop filter for loading a triangular wave signal with constant frequency on the control voltage Vctrl generated by the loop filter 305, so as to provide the CLK2 with a spread spectrum effect.

The spread ratio fixing circuit 320 mainly comprises a clock generating apparatus 321 and a spread spectrum charge pump circuit 323. The clock generating apparatus 321 is accomplished by a resistance-capacitance oscillator. The resistance-capacitance oscillator 321 provides a first clock signal CLK1 with constant frequency to the spread spectrum charge pump circuit 323. And then the spread spectrum charge pump circuit 323 charges/discharges the loop filter 305 according to the first clock signal CLK1, and thereby a triangular wave signal with constant frequency can be loaded on the control voltage signal Vctrl output by the loop filter 305.

FIG. 3B is a schematic circuit view of the spread spectrum charge pump circuit 323 according to one preferred embodiment of the invention. In the following description of the drawings, same numerals indicate identical elements and devices. Referring to FIG. 3B, switches 31, 33 are included in the spread spectrum charge pump circuit 323. The first end of the switch 31 is grounded via a current source I1, and the second end of the switch 31 is coupled to the first end of the switch 33 and then coupled to the loop filter 305 together. Likewise, the second end of the switch 33 is coupled to a current source I2. And the amount of the current generated by the current sources I1, I2 can be the same.

Next, referring to FIG. 3B, the on/off of switches 31, 33 is determined by the first clock signal CLK1 generated by the resistance-capacitance oscillator 301. However, as the output of the resistance-capacitance oscillator 321 controls the on/off of the switch 33 by the inverter 35, thus the action of the switch 33 and the action of the switch 31 are opposite. For example, when the first clock signal CLK1 is at the first level, the switch 31 is on, and correspondingly, the switch 33 is off. At this time, the loop filter 305 generates a spread spectrum current Issp to the spread spectrum charge pump circuit 323, i.e., the loop filter 305 performs discharging. Otherwise, if the first clock signal CLK1 is at a second level, the switch 31 is off, and the switch 33 is on. At this time, the spread spectrum charge pump circuit 323 outputs the spread spectrum current Issp to the loop filter 305 for charging the loop filter 305. As the resistance-capacitance oscillator 321 generates the first clock signal CLK1 with constant frequency, the frequency of the spread spectrum charge pump circuit 323 charging/discharging the loop filter 305 is also constant. Therefore, a triangular wave signal with constant frequency can also be loaded on the control voltage Vctrl when the control voltage Vctrl is generated by the loop filter 305.

The circuit as shown in FIG. 3B can also be applicable to the charge pump circuit 303 of FIG. 3A. The on/off of two switches in the charge pump circuit 303 is determined based on the comparison result of the reference clock signal CLK0 and the feedback clock signal CLK3 compared by the phase comparator 301. When the two switches are switched in the charge pump circuit 303, the charge pump circuit 303 charges/discharges the loop filter 305 for enabling the loop filter to generate the control voltage signal Vctrl.

Referring to FIG. 3A again, generally, the loop filter 305 can be divided into 1st-stage loop filter, 2nd-stage loop filter, and 3rd-stage loop filter. The 1st-stage loop filter is a capacitor for providing a zero point in the system. The 2nd-stage loop filter provides a polar point in addition to a zero point. The loop filter 305 in the present embodiment is a 2nd-stage loop filter. Therefore, only the 2nd-stage loop filter is illustrated as an example. However, those skilled in the art should understand that the loop filter 305 in the invention is not limited to a 2nd-stage loop filter.

Capacitors C1, C2 are included in the loop filter 305. The first end of the capacitor C1 is grounded, and its second end is coupled to the first end of the resistor R2. Likewise, the first end of the capacitor C2 is grounded, and its second end is coupled to the first end of the resistor R1, and then coupled to the charge pump circuit 303 and the VCO 310. When the charging current in different directions generated by the charge pump circuit 303 is input to the loop filter 305 from the second end of the resistor R1, the loop filter 305 sends the control voltage signal Vctrl from the second end of the capacitor C2 to the VCO 310. Furthermore, the second ends of the resistors R1, R2 are coupled to each other, and then both coupled to the spread spectrum charge pump circuit 323 together for receiving the spread spectrum current Issp.

FIG. 3C is a block circuit view of the VCO 310 according to a preferred embodiment of the invention. Referring to FIG. 3C, a voltage/current conversion circuit 312 is included in the VCO 310 for receiving the control voltage Vctrl generated by the loop filter 305, converting the control voltage Vctrl into a current signal Ictrl, and outputting the current signal Ictrl to the current controlled oscillator 314, so that the current controlled oscillator 314 is able to generate the spread spectrum clock signal CLK2. Furthermore, the output of the voltage/current conversion circuit 312 is also fed back to the spread spectrum charge pump circuit 323 for controlling the amplitude of the triangular wave signal loaded on the control voltage Vctrl.

When the VCO 310 is the linear operation, the frequency Fvco of the spread spectrum clock signal CLK2 can be represented by the following formula:
Fvco=a₀+Kvco·V (1)
where Kvco is the ratio of the frequency Fvco of the spread spectrum clock signal CLK2 to the control voltage Vctrl, and a0 is an offset. It should be noted that, at this time, the frequency Fvco of the spread spectrum clock signal CLK2 does not take the influence of the spread ratio fixing circuit 320 into consideration.

If the spread ratio fixing circuit 320 is added, the frequency Fvco of the spread spectrum clock signal CLK2 will generate an offset, called ΔFvco, which can be represented as follows:
ΔFvco=Kvco×ΔV (2)
By comparing the aforementioned formulas (1) and (2), the following formula can be obtained:

$$\frac{Δ Fosc}{Fosc} = \frac{Kvco \cdot Δ V}{{a}_{0} + Kvco \cdot {Vctrl}_{avg}}$$

As the offset a₀ is extremely small and can be ignored, the above formula can be:

$$\frac{Δ Fosc}{Fosc} ≅ \frac{Δ V}{{Vctrl}_{avg}} \qquad ( 3 )$$

Then, assume that the current signal Ictrl is represented by the following formula:

$$Ictrl = \frac{Vctrl}{Rv 21}$$

where Rv21 is the equivalent resistance of the voltage/current conversion circuit 312. As the current signal Ictrl can be fed back to the spread spectrum charge pump circuit 303, according to the above formula, the spread spectrum current Issp can be represented as follows:

$$Issp = l 1 \cdot \frac{Vctrl}{Rv 21}$$

where 11 is a proportional constant.

Furthermore, assume the product of the capacitance value of the capacitor C1 and the resistance value of the resistor R2 equals the product of the capacitance value of the capacitor C2 and the resistance value of the resistor R1, thus the following formula is obtained:

$$Δ V = {Vctrl}_{peak} - {Vctrl}_{avg} = \frac{Issp}{( C 1 + C 2 ) \cdot 2 Fvco}$$

where Vctrlₚₑₐₖ and Vctrl_{avg} are the peak voltage and averaged voltage of the control voltage Vctrl respectively. Additionally, Fvco is the oscillation frequency of the spread spectrum clock signal CLK2, which can be represented by the following formula:

$$Fvco = \frac{l 2}{Rvco \cdot Cvco}$$

where Rvco and Cvco are the equivalent resistance and capacitance of the VCO 310 respectively, and 12 is also a proportional constant.

Next, ΔV can be transformed into the following formula:

$$\begin{matrix}Δ V = \frac{l 1 \cdot \frac{{Vctrl}_{avg}}{Rv 21}}{( C 1 + C 2 ) \cdot 2 \frac{l 2}{Rvco \cdot Cvco}} \\ = l 3 \times \frac{Rvco}{Rv 21} \times \frac{Cvco}{( C 1 + C 2 )} \times {Vctrl}_{avg}\end{matrix}$$

where 13 is a proportional constant. After transposing the above formula, the ratio of ΔV to Vctrl_{avg} in the formula (3) can be proved a constant. Therefore, it can be known that the spread ratio of the spread spectrum clock signal generated by the PLL is kept constant according to the invention.

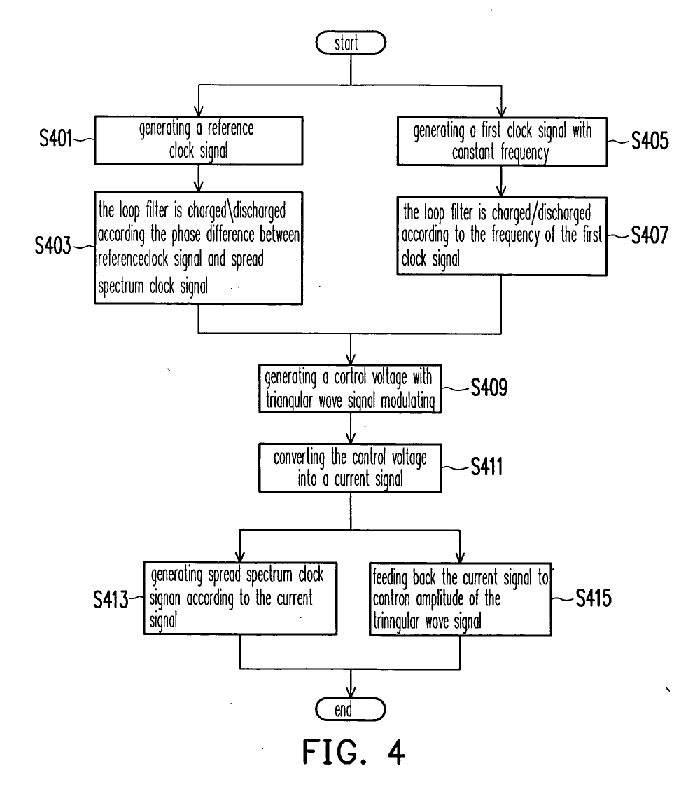

FIG. 4 is a flow chart of the steps for generating the spread spectrum clock signal according to a preferred embodiment of the invention. The method can be applied to the apparatus for generating the spread spectrum clock signal as shown in FIG. 3A. Referring to FIGS. 3A and 4, first, as shown in Step S401, a reference clock signal CLK0 is generated, and then the phase comparator 301 receives the reference clock signal CLK0 to compare it with the feedback clock signal CLK3. Then, the phase comparator 301 controls the charge pump circuit 303 to charge/discharge the loop filter 305 according to the comparison result, such that the control voltage Vctrl is generated, as shown in Step S403.

When the above steps are implemented, the resistance-capacitance oscillator 321 generates a first clock signal CLK1 with constant frequency, as shown in Step S405. Then, the spread spectrum charge pump circuit 323 charges/discharges the loop filter 305 according to the frequency of the first clock signal CLK1 (Step S407), such that a triangular wave signal is generated to modulate the control voltage Vctrl, as shown in Step S409.

Next, the voltage/current conversion circuit 312 in the VCO 310 (as shown in FIG. 3C) performs Step S411, i.e., converts the control voltage Vctrl into the current signal Ictrl. Then, the current controlled oscillator 314 (as shown in FIG. 3C) generates the spread spectrum clock signal CLK2 according to the current signal Ictrl, as shown in Step S413. At this time, the VCO 310 can also feed the current signal Ictrl back to the spread spectrum charge pump circuit 323, as shown in Step S415, so as to control the amplitude of the aforementioned triangular wave signal.

In view of the above, the present invention at least has the following advantages:

1. According to the invention, as the constant clock signal generated by the resistance-capacitance oscillator is input into the spread spectrum charge pump circuit to replace the reference clock signal, and the control current generated by the voltage/current conversion circuit is fed back to the loop filter, the spread ratio and the amplitude of the clock signal generated by the current controlled oscillator can be kept constant.

2. As described, the present invention employs the constant clock signal to replace the reference clock signal, and uses the control current of the reference PLL to determine the spread spectrum current, thus the spread ratio can be kept constant even under the reference clock signals of different frequencies.

3. Deduced from the above mathematical formulas, the spread ratio does not have a relationship with the absolute values of the resistance value and the capacitance value, but with their relative values. Though the resistance value and the capacitance value vary due to process excursion, their relative values remain constant. In other words, the constant spread ratio is not likely to be affected by process excursion.

Though the present invention has been disclosed above by the preferred embodiments, it is not intended to limit the invention. Anybody skilled in the art can make some modifications and variations without departing from the spirit and scope of the invention. Therefore, the protecting range of the invention falls in the appended claims.

What is claimed is:

1. A spread ratio fixing circuit, applicable to a phase lock loop (PLL) for receiving a inputting clock signal and outputting a spread spectrum clock signal, wherein the PLL has a loop filter, the spread ratio fixing circuit comprising:
a clock generating apparatus, for generating a first clock signal with constant frequency; and
a spread spectrum charge pump circuit, coupled to the loop filter, for charging/discharging the loop filter according to the first clock signal, so as to load a triangular wave signal with constant frequency on a control voltage output by the loop filter.

2. The spread ratio fixing circuit according to claim 1, wherein the PLL further comprises:
a phase comparator, for outputting a comparison result based on a feedback clock signal and the inputting clock signal;
a charge pump circuit, for generating a charging current in different directions according to the comparison result and sending the charging current to the loop filter;
a voltage controlled oscillator (VCO), coupled to the loop filter, for generating a current signal and the spread spectrum clock signal according to the control voltage signal and feeding the current signal back to the spread spectrum charge pump circuit, so as to control the amplitude of the triangular wave signal; and
a frequency divider, for generating the feedback clock signal to the phase comparator after dividing the frequency of the spread spectrum clock signal.

3. The spread ratio fixing circuit according to claim 2, wherein the VCO comprises:
a voltage/current conversion circuit, for converting the control voltage into the current signal; and
a current controlled oscillator, for generating the spread spectrum clock signal according to the current signal.

4. The spread ratio fixing circuit according to claim 1, wherein the loop filter comprises:
a first capacitor, with the first end grounded;
a second capacitor, with the first end grounded;
a first resistor, with the first end coupled to the spread spectrum charge pump circuit, and the second end coupled to the second end of the second capacitor; and
a second resistor, with the first end coupled to the second end of the first capacitor, and the second end coupled to the first end of the first resistor.

5. The spread ratio fixing circuit according to claim 4, wherein the product of the resistance value of the first resistor and the capacitance value of the second capacitor equals to the product of the resistance value of the second resistor and the capacitance value of the first capacitor.

6. The spread ratio fixing circuit according to claim 1, wherein the spread spectrum charge pump circuit comprises:
a first switch, with the first end grounded via a first control current source, wherein the on/off of the first switch is determined by the first clock signal;
a second switch, with the first end coupled to the second end of the first switch, and the second end coupled to a second control current source, wherein the amounts and directions of the current output by the first current source and the current output by the second current source are the same; and
an inverter, receiving the first clock signal, for controlling the on/off of the second switch.

7. The spread ratio fixing circuit according to claim 1, wherein the clock generating apparatus comprises a resistance-capacitance oscillator.

8. A method for generating the spread spectrum clock signal, applicable to a PLL, wherein the PLL comprises a loop filter, the generating method comprising:
generating a reference clock signal;
charging/discharging the loop filter according to the phase difference between the reference clock signal and the spread spectrum clock signal for generating a control voltage;
generating a first clock signal with constant frequency;
charging/discharging the loop filter according to the frequency of the first clock signal for loading a triangular wave signal on a control voltage output by the loop filter; and
generating the spread spectrum clock signal according to the control voltage.

9. The method for generating the spread spectrum clock signal according to claim 8, further comprising:
converting the control voltage into a current signal; and
oscillating to obtain the spread spectrum clock signal according to the current signal.

10. The method for generating the spread spectrum clock signal according to claim 9, further comprising feeding back the current signal so as to control the amplitude of the triangular wave signal.

11. The method for generating the spread spectrum clock signal according to claim 8, wherein the first clock signal is generated by a resistance-capacitance oscillator.
